(19) United States
(12) Patent Application Publication
(10) Pub. No.: US 2024/0339321 A1
(43) Pub. Date: Oct. 10, 2024

(54) METHODS, SYSTEMS, AND STRUCTURES FOR PATTERNING SUBSTRATES

(71) Applicant: ASM IP Holding B.V., Almere (NL)

(72) Inventors: Kishan Ashokbhai Patel, Leuven (BE); Ikhlas Rahmat, Leuven (BE); Yoann Tomczak, Leuven (BE); Charles Dezelah, Helsinki (FI); David Kurt de Roest, Leuven (BE)

(21) Appl. No.: 18/624,866

(22) Filed: Apr. 2, 2024

Related U.S. Application Data
(60) Provisional application No. 63/494,146, filed on Apr. 4, 2023.

(51) Int. Cl. H01L 21/027; G03F 7/004

(52) U.S. Cl. CPC H01L 21/0274; G03F 7/0042

(57) ABSTRACT

Structures, related methods, and related systems are disclosed. An embodiment of a structure comprises a resist and an inhibition layer. The EUV resist comprises exposed resist areas and unexposed resist areas. The inhibition layer inhibits the unexposed resist areas versus the exposed resist areas with respect to vapor phase deposition of a hard mask.

### CROSS-REFERENCE TO RELATED APPLICATION(S)

This application claims the benefit of U.S. Provisional Application 63/494,146 filed on Apr. 4, 2023, the entire contents of which are incorporated herein by reference.

### FIELD OF INVENTION

The present disclosure is in the field of integrated circuit manufacture, in particular in the field of Front-end-of-Line Patterning, more particular in the field of extreme ultraviolet (EUV) patterning.

### BACKGROUND OF THE DISCLOSURE

Devices in the integrated circuits (ICs) are scaling down rapidly. Fabrication of such devices requires multiple steps, one of the main bottleneck in the fabrication is lithography step. Currently, extremely small features are realized using multi-patterning approaches. This leads to a significant increase in the number of lithography steps, increases in the cost of operation, and increases in the probability of defects and placement error.

Extreme Ultraviolet (EUV) lithography is a technique that can avoid or reduce the need for multiple patterning. The smallest feature which can be patterned onto various photoresist with acceptable defectivities using EUV lithography is limited by the resolution of EUV tool. Thus far, achieved resolution on the resist is far from what it can be obtained theoretically from EUV tools. That is mainly because at very small feature size photoresist does not have sufficient mechanical strength to hold its shape after development, leading to collapse/wiggling of the patterns or having very rough edges/shapes.

To mitigate this problem to some extent, the thickness of photoresist can also be scaled down with decreasing feature size. However, this reduces the etch resistance of the photoresist film during the pattern transfer to hard mask. Furthermore, glue layers for improving adhesion of photoresists can make pattern transfer even more complicated since the photoresist has to provide good etch resistance to etch both glue layer as well as the hard mask layer underneath.

The above challenges notwithstanding, extreme ultraviolet (EUV) lithography is becoming mainstream method for the fabrication of semiconductor devices with the critical dimensions below 20 nm, which helps in solving the problem with resolution of the lithography tool. In order to enhance the resolution, reduce the defectivity, and control the costs associated with EUV lithography, there remains a need for improved materials and material systems.

### SUMMARY OF THE DISCLOSURE

Methods, structures, and systems described herein can advantageously allow defining small features in a single exposure, particularly in the field of extreme ultraviolet (EUV) lithography. In some embodiments, methods and structures according to the present disclosure comprise modifying an organic/inorganic, e.g. resist, layer using lithography, e.g. EUV lithography. In some embodiments, the teachings of the present disclosure allow using vapor-deposited resists instead of spin-on resist, which can be particularly advantageous for providing resist layers having a smaller thickness than spin-on resists. In some embodiments, the teachings of the present disclosure comprise using modified/unmodified resist surface to deposit one or more of a hard mask, a metal, a dielectric, and a semiconductor.

In some embodiments, the teachings of the present disclosure comprise depositing uniform EUV-sensitive films using a cyclical deposition method such as ALD. Exposure of the EUV-sensitive film to EUV radiation can change the surface functionality to help selectively deposit various films, e.g. hard masks, onto it using ALD/CVD/MLD methods.

In one aspect, described herein is a structure comprising a substrate, an extreme ultraviolet (EUV) resist, and an inhibition layer, wherein the EUV resist comprises exposed resist areas and unexposed resist areas, and, wherein the inhibition layer inhibits the unexposed resist areas versus the exposed resist areas with respect to vapor phase deposition of a hard mask.

In some embodiments, the structure further comprises a hard mask on the exposed resist areas.

In some embodiments, the inhibition layer comprises a surface termination selected from alkyl, alkenyl, alkynyl, aryl, fluorinated hydrocarbyl, amine, silyl, and alkylsilyl.

In some embodiments, the EUV resist is selected from a metal oxide resist, chemically amplified resist, and acrylate polymer-based resist.

In some embodiments, the EUV resist comprises a metalorganic framework.

In some embodiments, the hard mask comprises one or more materials selected from metals, semiconductors, and dielectrics.

In some embodiments, the inhibition layer comprises a surface group selected from the list consisting of alkane, alkene, alkyne, aromatic, fluorocarbon, and amine.

In some embodiments, the exposed resist comprises one or more surface terminations selected from dangling bond, carboxyl, hydroxyl, and amine.

In a further aspect, described herein is a method of forming a structure, the method comprising: providing a substrate; forming an EUV resist on the substrate; and, contacting the substrate with an inhibitor, thereby forming an inhibition layer on the EUV resist, wherein, upon EUV exposure through a mask, exposed resist areas and unexposed resist areas are formed, the unexposed resist areas being inhibited by the inhibition layer.

In some embodiments, the method further comprises exposing the substrate through a mask, thereby forming the exposed resist areas and the unexposed resist areas, the unexposed resist areas being inhibited by the inhibition layer versus the exposed areas with respect to vapor phase deposition of a hard mask.

In some embodiments, the inhibitor comprises a moiety selected from alkane, alkene, alkyne, aromatic, fluorocarbon, and amine.

In some embodiments, the inhibitor comprises a compound selected from the list consisting of alkylamines, halogenated carbons, and alkanolamines.

In some embodiments, the inhibitor comprises a compound selected from the list consisting of silazanes, sylylamines, alkylgermanes, and heterocyclic compounds.

In some embodiments, a method as described herein comprises selectively depositing a hard mask on the exposed areas with respect to the unexposed areas.

In some embodiments, the hard mask is selectively deposited using a vapor phase deposition technique selected from molecular layer deposition, atomic layer deposition, and chemical vapor deposition.

In some embodiments, the hard mask is deposited at a temperature of at most 150° C.

In some embodiments, the hard mask comprises an oxide.

In some embodiments, the EUV resist is formed by means of molecular layer deposition.

In a further aspect, described herein is a system comprising one or more precursor sources, a reaction chamber operationally coupled with the one or more precursor sources, and a controller, the controller being arranged for causing the system to carry out a method as described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1A shows an embodiment of a structure as described herein.

FIG. 1B shows an embodiment of a structure as described herein.

FIG. 1C shows an embodiment of a structure as described herein.

FIG. 2A shows an embodiment of a method as described herein.

FIG. 2B shows an embodiment of a method as described herein.

FIG. 2C shows an embodiment of a method as described herein.

FIG. 3 shows an embodiment of a cyclical deposition process.

FIGS. 4-9 shows embodiments of systems and sub-systems as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

Throughout this disclosure, Me stands for methyl, Et stands for ethyl, iPr stands for isopropyl, Ph stands for phenyl. Chemical elements may be abbreviated using their standard symbol.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices. A film or layer may be selectively grown on some parts of a substrate, and not on others.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant.

It shall be understood that purges and pulses can be effected either in time or in space, or both. For example, in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied. For example, in the case of temporal pulses, a precursor can be provided for a pre-determined amount of time before and after which an inert gas is provided to the reaction chamber. For example, in the case of spatial pulses, a substrate can be moved through a pre-determined location at which precursor is provided and which is surrounded by one or more inert purge gas curtains.

As used herein, a “precursor” includes a gas or a material that can become gaseous and that can be represented by a chemical formula that includes an element which may be incorporated during a deposition process as described herein.

The term “oxygen reactant” can refer to a gas or a material that can become gaseous and that can be represented by a chemical formula that includes oxygen. In some cases, the chemical formula includes oxygen and hydrogen.

The term “nitrogen reactant” can refer to a gas or a material that can become gaseous and that can be represented by a chemical formula that includes nitrogen. In some cases, the chemical formula includes nitrogen and hydrogen.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like.

As used herein, the term “comprising” indicates that certain features are included, but that it does not exclude the presence of other features, as long as they do not render the claim or embodiment unworkable. In some embodiments, the term “comprising” includes “consisting”. As used herein, the term “consisting” indicates that no further features are present in the apparatus/method/product apart from the ones following said term. When the term “consisting” is used referring to a chemical compound, it indicates that the chemical compound only contains the components which are listed.

In this disclosure, any defined meanings do not necessarily exclude ordinary and customary meanings, in some embodiments.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

After exposure, EUV resists will contain exposed regions and unexposed regions. For optimal contrast between the surfaces, and in accordance with embodiments of the present disclosure, an inhibition layer can be employed to prevent growth on the unexposed areas during hard mask deposition onto the exposed areas. In some embodiments, disclosed herein are structures and related methods and systems for inhibition and lists some types of surface chemical functional groups that can provide such inhibition, and related selective hard mask deposition.

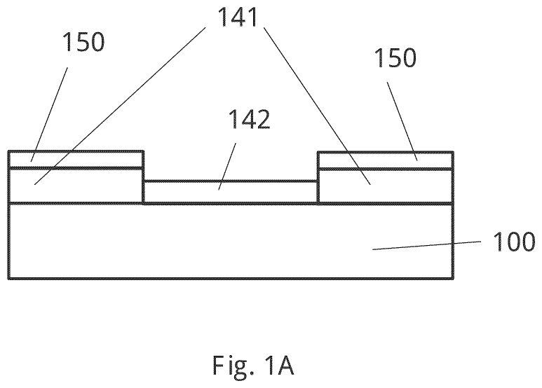

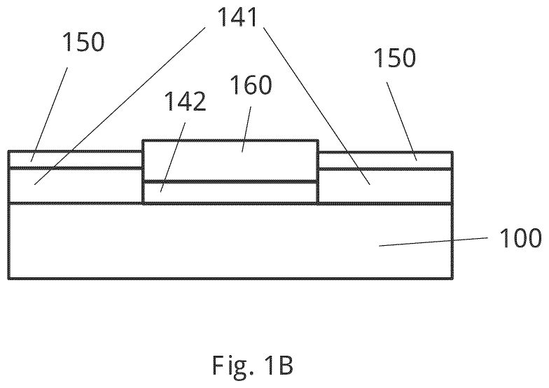

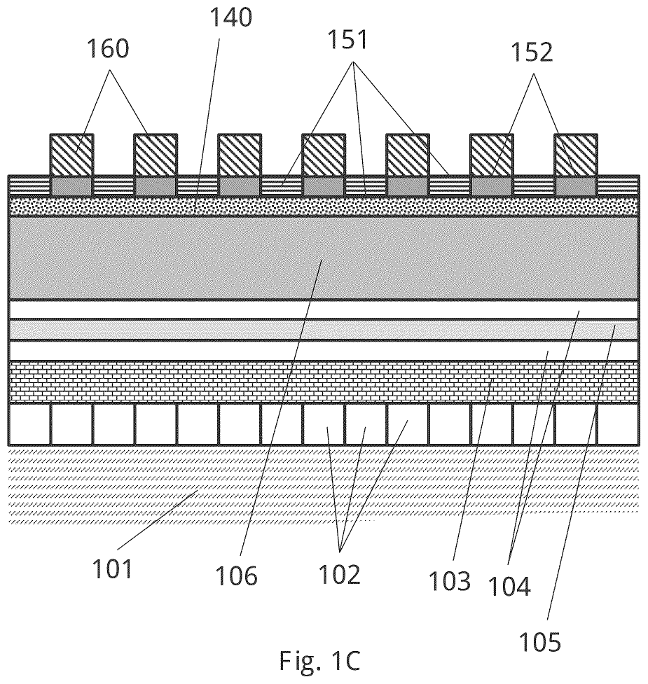

With reference to FIG. 1A, an embodiment of a structure is described. The structure comprises a substrate 100, an extreme ultraviolet (EUV) resist, and an inhibition layer 150. The EUV resist comprises exposed resist areas 142 and unexposed resist areas 141. The inhibition layer 150 inhibits the unexposed resist areas 141 versus the exposed resist areas 142 with respect to vapor phase deposition of a hard mask.

As shown in FIG. 1B, a structure according to FIG. 1A can further comprise a hard mask 160 on the exposed resist areas. Such a hard mask 160 can be formed, for example, by selectively depositing the hard mask by means of a vapor-phase deposition technique such as chemical vapor deposition, atomic layer deposition, plasma-enhanced atomic layer deposition, plasma-enhanced chemical vapor deposition, or molecular layer deposition. Alternatively, a hard mask 160 can be formed by means of other forming techniques such as selective deposition from a liquid phase, e.g. by means of a plating technique.

FIG. 1C shows another embodiment of a structure as described herein. In particular, FIG. 1C shows how a substrate can comprise multiple layers. In particular, the substrate can comprise a wafer 101, such as a silicon wafer. On the wafer 101, various previous patterns 102 can be formed. A layer to be patterned 103 can be present on the various previous patterns 102. A first hard mask can be formed on the various previous patterns 102. The first hard mask can comprise a silicon nitride layer 105 that can be sandwiched between two silicon oxide layers 104. A second hard mask 106 comprising amorphous carbon can be formed on the first hard mask.

A resist 140 can be formed on the second hard mask 106. An inhibitor layer can be formed on the resist 140. The inhibitor layer can comprise exposed inhibitor areas 152 and unexposed inhibitor areas. A third hard mask 160 is present on the exposed inhibitor areas 152, and not on the unexposed inhibitor areas.

As shown in FIG. 1C, the resist 140 is a monolithic layer and the nature of the inhibitor layer is different in the exposed areas and the unexposed areas, which can give rise to selectivity with respect to certain deposition chemistries. While this is certainly a possibility, other possibilities exist as well, as shown e.g. in the embodiments of FIGS. 1A and 1B. In particular, the photoresist can undergo structural changes upon exposure to radiation, e.g. EUV radiation. In some embodiments, the inhibitor, e.g. inhibitor, can be removed from the resist in the exposed resist areas.

In either case, inhibitor passivates the resist in unexposed resist areas. The exposed resist areas comprise active surface groups such that a hard mask 160 can be selectively formed on the exposed inhibitor areas 152, and not, or not substantially, on the unexposed inhibitor areas 151. In other words, the hard mask can be selectively formed on exposed resist areas not passivated by the inhibitor layer, and not, or not substantially, on unexposed resist areas which are passivated by the inhibitor layer.

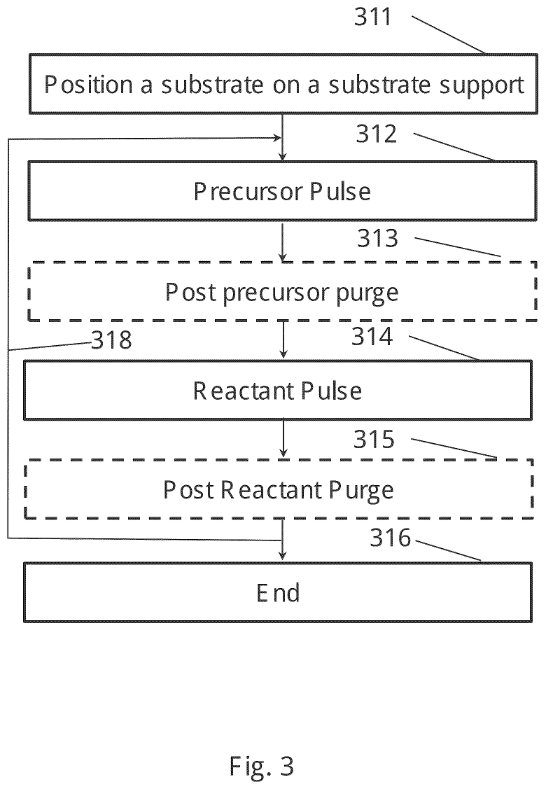

In some embodiments, an inhibition layer comprising a fluorinated hydrocarbyl surface termination can be obtained by executing one or more inhibition layer forming cycles, such as from 1 to 100 cycles, or from 1 to 5 cycles, or from 5 to 25 cycles, or from 25 to 100 cycles. An inhibition layer forming cycle can comprise a inhibition layer precursor pulse and an inhibition layer reactant pulse. An inhibition layer precursor pulse can comprise contacting the substrate with an inhibition layer precursor. An inhibition layer reactant pulse can comprise contacting the substrate with an inhibition layer reactant pulse. An exemplary schematic representation of a cyclic deposition process such as atomic layer deposition or molecular layer deposition is shown in FIG. 3, which is discussed in detail elsewhere herein.

In some embodiments, the inhibition layer comprises a surface termination selected from alkyl, alkenyl, alkynyl, aryl, fluorinated hydrocarbyl, amine, silyl, and alkylsilyl.

For example, an inhibition layer comprising an alkyl surface termination can be obtained by exposing the substrate to a compound that has the formula N(R1)₂(R2) or N(R1)(R2)₂, wherein R1 is an alkyl such as a C1 to C6 alkyl, such as methyl, ethyl, propyl, or butyl; and wherein R2 is an alkylsilyl. In some embodiments, R2 can have the formula —Si(R3)₃ wherein R3 is a C1 to C6 alkyl such as methyl, ethyl, propyl, or butyl. In some embodiments, R1 is methyl and R2 is trimethylsilyl.

For example, an inhibition layer comprising an alkyl surface termination can be obtained by exposing the substrate to a chloroalkyl germane such as chloro(triethyl) germane.

For example, an inhibition layer comprising an alkenyl surface termination can be obtained by exposing the substrate to a compound comprising silicon or germane, an alkenyl group, and optionally one or more of a halogen and an alkoxy group. For example, an inhibition layer comprising an alkenyl surface termination can be obtained using a compound selected from the list consisting of allyltrichlorogermane, allyl(dichloro)methylsilane, dichloromethylvinylsilane, and vinyltriethoxysilane.

For example, an inhibition layer comprising an alkynyl surface termination can be obtained using by exposing the substrate to a compound that has the formula N(R1)₂(R2) or N(R1)(R2)₂, wherein R1 is an alkyl such as a C1 to C6 alkyl, such as methyl, ethyl, propyl, or butyl; and wherein R2 is an alkylsilyl. In some embodiments, R2 can have the formula —Si(R3)₃ wherein R3 is a C1 to C6 alkyl such as methyl, ethyl, propyl, or butyl. In some embodiments, R1 is methyl and R2 is trimethylsilyl. For example, an inhibition layer comprising an aryl surface termination can be obtained using an inhibitor comprising germanium, a phenyl functional group, and optionally at least one of an alkyl functional group and a halogen. For example, suitable compounds comprise phenyldimethylchlorogermane and trichlorophenylgermane.

For example, an inhibition layer comprising a fluorinated hydrocarbyl surface termination can be obtained by executing one or more inhibition layer forming cycles. Suitable inhibition layer precursors can comprise an alkylamido ligand such as a dimethylamido ligand, and a metal center such as tin. For example, the inhibition layer precursor can comprise tetrakis(dimethylamido) tin. Suitable inhibition layer reactants can comprise halogenated diols, for example fluorinated diols, such as hexafluoro-2-propanol.

For example, an inhibition layer comprising an amine surface termination can be obtained by executing one or more inhibition layer forming cycles. Suitable inhibition layer precursors can comprise an alkylamido ligand such as a dimethylamido ligand, and a metal center such as tin. For example, the inhibition layer precursor can comprise tetrakis(dimethylamido) tin. Other possible inhibition layer precursors include maleic anhydride and fumaric acid. Suitable inhibition layer reactants can include diamines such as 1 6-hexanediamine and ethylenediamine. In some embodiments, the inhibition layer reactant can comprise a bifunctional molecule comprising an amine group and a hydroxyl group, such as ethanolamine.

For example, an inhibition layer comprising a silyl or alkylsilyl surface termination can be obtained by exposing the substrate to a compound that has the formula N(R1)₂(R2) or N(R1)(R2)₂, wherein R1 is H or an alkyl such as a C to C6 alkyl, such as methyl, ethyl, propyl, or butyl; and wherein R2 is silyl or alkylsilyl. In some embodiments, R2 can have the formula —Si(R3)₃ wherein R3 is H or a C1 to C6 alkyl such as methyl, ethyl, propyl, or butyl. In some embodiments, R1 is methyl and R2 is trimethylsilyl. In some embodiments, R1 is methyl and R2 is silyl.

In some embodiments, the inhibition layer comprises a surface group selected from the list consisting of alkyl, alkenyl, alkynyl, aryl, fluoroalkyl, fluoroalkenyl, fluoroalkynyl, fluoroaryl, and amino.

It shall be understood that the terms “surface group” and “surface termination” as used herein can be used interchangeably.

In some embodiments, the inhibition layer does not comprise any surface groups that readily react with water or halides. For example, in some embodiments, the inhibition layer does not comprise hydroxyl or carboxyl surface terminations.

Suitably, the exposed resist areas comprise a surface termination that can readily react with water or a halide. Examples of suitable surface terminations of the exposed resist areas include hydroxyl groups, dangling bonds, amines, and carboxyl groups.

In some embodiments, the EUV resist is selected from a metal oxide resist, chemically amplified resist, and acrylate polymer-based resist. The resist can be positive or negative tone. It shall be understood that EUV resists are, as such, known in the art. Some embodiments of suitable resists are described in United States Provisional Application no. U.S. 63/330,568 which is incorporated herein by reference in its entirety.

In some embodiments, the EUV resist comprises a metalorganic framework.

In some embodiments, the EUV resist comprises one or more EUV-radiation absorbing elements such as tin, antimony, indium, tellurium, germanium, hafnium, and zirconium

In some embodiments, the EUV resist contains a surface termination selected from carboxylic acid (—COOH), ester (—COOR), and hydroxyl (—OH) groups, with R being alkyl, aryl, alkenyl, alkynyl, or hydrocarbyl.

In some embodiments, the hard mask comprises one or more materials selected from metals, semiconductors, and dielectrics. Suitable hard masks include transition metal oxides such as titanium oxide, transition metal oxycarbides such as titanium oxycarbide, group 13 element oxides such as aluminum oxide, group 13 element oxycarbides such as aluminum oxycarbide, group 14 element oxides such as silicon oxide, and group 14 element oxycarbides such as silicon oxycarbide.

In some embodiments, the hard mask can be formed, using a cyclic deposition process such as atomic layer deposition (ALD). Such a cyclic deposition process can comprise a plurality of cycles. Ones from the plurality of cycles comprise a hard mask precursor pulse and a hard mask reactant pulse. The hard mask precursor pulse can comprise exposing the substrate to a hard mask precursor. The hard mask reactant pulse can comprise exposing the substrate to a hard mask reactant.

In an exemplary embodiment, the hard mask can comprise a or a metal chalcogenide such as a metal oxide, such as a transition metal chalcogenide such as titanium oxide. A titanium oxide hard mask can be formed, in some embodiments, using a cyclic deposition process such as atomic layer deposition (ALD). The hard mask precursor can comprise a transition metal halide such as TiCl₄ and the hard mask reactant can comprise an oxygen reactant such as H₂O. Such a hard mask can be selectively grown on hydroxyl-terminated exposed resist, versus halogenated carbon-terminated unexposed resist. For example, the unexposed non-growth surface can comprise surface groups that comprise Cl or F linked to carbon. Also, such a hard mask can be selectively grown on hydroxyl-terminated exposed resist, versus alkyl-terminated unexposed resist. Suitable alkyl terminations include alkyl, alkylsilyl, and alkylgermyl.

In some embodiments, a structure as described herein comprises a glue layer. The glue layer can provide adhesion between the resist, e.g. EUV resist, and an underlying layer. Suitable underlying layers include layers to be patterned and amorphous carbon. In some embodiments, the glue layer comprises silicon, oxygen, and carbon. In some embodiments, the glue layer can comprise silicon oxycarbide. In some embodiments, the glue layer can further comprise nitrogen. In some embodiments, the glue layer can comprise silicon oxycarbonitride. In some embodiments, the glue layer further comprises hydrogen. The glue layer can be formed using a thermal or a plasma vapor phase deposition process. For example, the glue layer can be formed by means of thermal or plasma-enhanced atomic layer deposition.

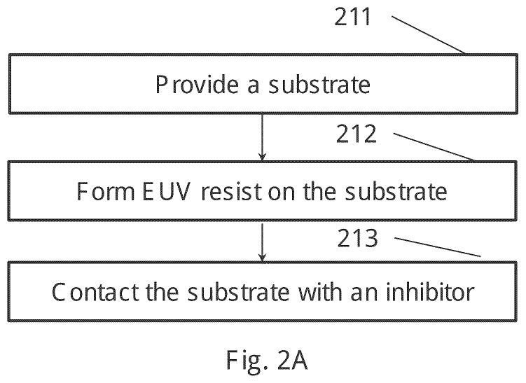

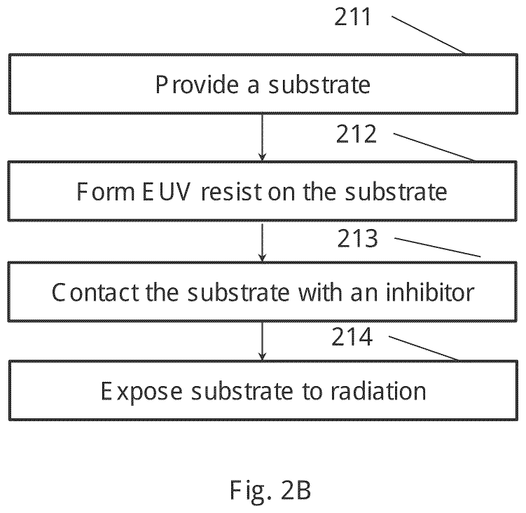

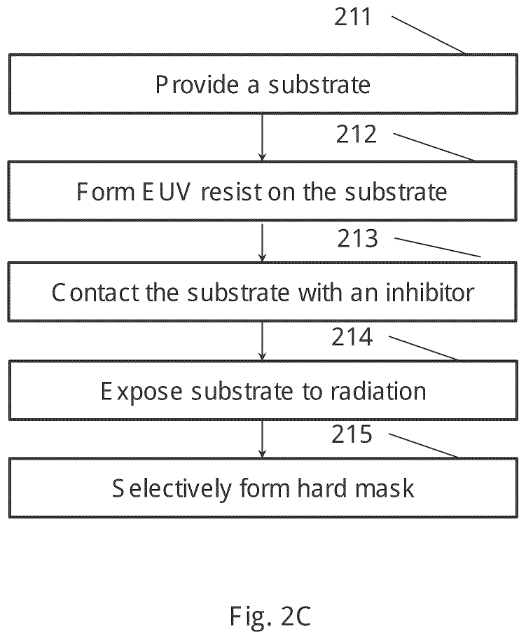

Further described herein is an embodiment of a method for forming a structure such as a structure according to the embodiment of FIG. 1A. Such an embodiment of a method is described referring to FIG. 2A. The embodiment of FIG. 2A shows steps of providing a substrate 211, subsequently forming an EUV resist on the substrate 212, and then contacting the substrate with an inhibitor 213. Thus, an inhibitor layer is formed upon the EUV resist. It shall be understood that, upon EUV exposure through a mask, exposed resist areas and unexposed resist areas are formed. The unexposed resist areas are inhibited by the inhibition layer and the exposed resist areas are reactive such that a hard mask can be selectively formed on the exposed resist areas (and not on the unexposed resist areas).

In some embodiments, the EUV resist is formed by means of molecular layer deposition. One suitable method of forming an EUV resist is described in United States Provisional Application no. U.S. 63/330,568 which is incorporated herein by reference in its entirety. Another suitable method of forming an EUV resist is described in United States Provisional Application no. U.S. 63/431,337 which is incorporated herein by reference in its entirety.

As shown in the embodiment of FIG. 2B, a method as described herein can further comprise a step 214 of exposing the substrate through a mask. The substrate can be particularly exposed to electromagnetic radiation such as EUV radiation, UV radiation, or visible light. Thus, exposed resist areas and unexposed resist areas are formed. The unexposed resist areas are inhibited by the inhibition layer versus the exposed areas with respect to vapor phase deposition of a hard mask, whereas a hard mask can be suitably and selectively deposited on the exposed resist areas versus the unexposed areas.

In some embodiments, exposed resist areas comprise hydroxyl surface terminations. In other words, EUV exposure can convert inhibited resist surfaces to hydroxyl-terminated surfaces. For example, this can happen through one or more of cleaving and oxidation of the inhibited surface. Additionally or alternatively, conversion of inhibited surfaces to hydroxyl-terminated resist surfaces can happen by decomposition of resist, which can also result in removing of the inhibition layer from the resist surface.

Suitable resists include EUV resists. An EUV resist layer may include any suitable resist, such as molecular, metal oxide, or chemically amplified resist. It shall be understood that the resists can be formed using any suitable deposition technique, including chemical vapor deposition (CVD), plasma-enhanced chemical vapor deposition (PECVD), atomic layer deposition (ALD), and plasma-enhanced atomic layer deposition (PEALD).

As shown in the embodiment of FIG. 2C, a method as described herein can further comprise a step 215 of selectively forming, e.g. depositing, a hard mask on the exposed areas with respect to the unexposed areas. A hard mask, once formed, can be used to protect the exposed areas during a subsequent etch, which allows pattern transfer to the substrate.

In some embodiments, the hard mask is not, or not substantially, formed on the unexposed areas.

In some embodiments, the hard mask has a thickness on the exposed resist areas of at least 1 nm, or of at least 2 nm, or of at least 5 nm, or of at least 10 nm.

Advantageously, the hard mask can be pinhole-free.

In some embodiments, the hard mask is selectively deposited using a vapor phase deposition technique selected from molecular layer deposition, atomic layer deposition, and chemical vapor deposition. Alternatively, the hard mask can be formed by any other suitable selective deposition technique such as a liquid phase selective deposition technique such as electroless plating.

In some embodiments, the hard mask is deposited at a temperature of at most 150° C. This can be advantageous for limiting the thermal budget to the substrate, the resist, and the inhibitor.

In some embodiments, the hard mask comprises an oxide.

In some embodiments, selectively forming the hard mask on the exposed resist areas can be done using a metal precursor, e.g. a transition metal or rare earth metal precursor, and an oxygen reactant such as water.

In some embodiments, the hard mask can be selectively formed on the exposed resist areas using an inorganic-organic molecular layer deposition (MLD) process. For example, the MLD process can comprise a plurality of cycles, ones from the plurality of cycles comprising a precursor pulse and a reactant pulse. During the precursor pulse, the substrate can be exposed to a metal precursor, e.g. a transition metal precursor, e.g. a titanium precursor, e.g. a titanium halide, e.g. TiCl₄. During the reactant pulse the substrate can be exposed to a bifunctional molecule, e.g. a dipole, e.g. ethylene glycol. For example, the substrate can be maintained at a temperature below 200° C. during hard mask formation. For example, the substrate can be maintained at a temperature of 100° C. during hard mask formation.

In some embodiments, the inhibitor can be easily volatilized and is thermally stable up to a temperature of at least 150° C. in an inert atmosphere.

In some embodiments, the inhibitor comprises a compound having the formula (R1), (M)(R2)₄₋ₙ, with R1 an attaching group selected from halogen, amine, alkylamine, dialkylamine, wherein M is Si or Ge, wherein R2 is a protecting group selected from a C1 to C8 hydrocarbyl, and wherein n is an integer from at least 1 to at most 3. Preferably, n equals 1.

Without wishing to be bound by any particular theory or mode of operation, it is believed that attaching groups can suitably form a volatile reaction product with a surface group of an EUV resist, and that protecting groups can bond to the EUV resist, thereby passivating nucleation sites for deposition of hard mask. The resulting protecting groups thus form an inhibition layer on the EUV resist. EUV exposure through a mask can then result in a substrate comprising exposed areas and unexposed areas. A hard mask can be selectively deposited on the exposed areas from which the inhibition layer has been at least partially removed vis-à-vis the unexposed areas that comprise the inhibition layer in a substantially pristine form.

In some embodiments, R2 is selected from the list consisting of alkyl, alkynyl, fluorohydrocarbyl, C1-C8 saturated or unsaturated linear hydrocarbyl, and aryl.

Examples of inhibitors include Me₃SiCl, Me₃SiBr, Et₃SiCl, iPr₃SiCl, Ph₃SiCl, Ph₃SiBr, Me₃Si(NMe₂), Me₃Si(imidazole), Me₃Si(pyrrole), Me₃Si(pyrrolidine), SiMe₂Cl₂, SiEt₂Cl₂, Si(iPr)₂Cl₂, SiPh₂Cl₂, SiPh₂Br₂, SiMe₂(NMe₂)₂, Si(iPr)₂(NMe₂)₂, SiCl₃(tBu), SiCl₃ (n-hexyl), SiCl₃Ph, SiMe(NMe₂)₃, Si(n-hexyl)(NMe₂)₃, Me₃GeCl, Me₃GeBr, Et₃GeCl, iPr₃GeCl, Ph₃GeCl, Ph₃GeBr, Me₃Ge(NMe₂), Me₃Ge(imidazole), Me₃Ge(pyrrole), Me₃Ge(pyrrolidine), GeMe₂Cl₂, GeEt₂Cl₂, Ge(iPr)₂Cl₂, GePh₂Cl₂, GePh₂Br₂, GeMe₂(NMe₂)₂, Ge(iPr)₂(NMe₂)₂, GeCl₃(tBu), GeCl₃(n-hexyl), GeCl₃Ph, GeMe(NMe₂)₃, and Ge(n-hexyl)(NMe₂)₃.

In some embodiments, the inhibitor comprises a chemical group that reacts with one or more surface-terminating groups selected from carboxylic acid (—COOH), ester (—COOR), and hydroxyl (—OH) groups, with R being alkyl, aryl, alkenyl, alkynyl, or hydrocarbyl.

In some embodiments, the inhibitor comprises an acyl halide having the formula

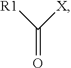

with R1 being hydrocarbyl such as Hydrocarbyl can include alkyl, alkynyl, fluorohydrocarbyl, C1-C8 saturated or unsaturated linear hydrocarbyl, aryl; and with X being a halogen such as F, Cl, Br, and I.

In some embodiments, the inhibitor comprises an acid anhydride having the formula

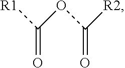

with R1 and R2 independently selected from a hydrocarbyl. Suitable hydrocarbyls include moieties selected from the list consisting of alkyl, alkynyl, fluorohydrocarbyl, C1-C8 saturated or unsaturated linear hydrocarbyl, and aryl.

In some embodiments, the inhibitor comprises a haloalkylphosphine having the formula (R1)ₙP(R2)₃₋ₙ, with R1 being selected from the list consisting of halogen, amino, alkylamino, dialkylamino, silyl, and alkyl silyl; with R2 being a hydrocarbyl, the hydrocarbyl optionally being selected from the list consisting of alkyl, alkynyl, fluorohydrocarbyl, C1-C8 saturated or unsaturated linear hydrocarbyl, and aryl; and with n being 1 or 2, n preferably being 1.

In some embodiments, the inhibitor comprises a silazane having the formula R1-NH—R2 with R1 and R2 independently selected from alkylsilyl. Suitable alkylsilyls include trimethylsilyl, triethylsilyl, and triisopropylsilyl.

In some embodiments, the inhibitor comprises one or more of a Si—Cl bond, a Si—NR₂ bond, and an acyl halide moiety, with R being alkyl, aryl, alkenyl, alkynyl, or hydrocarbyl.

In some embodiments, the inhibitor comprises a chemical group that is unreactive toward subsequent exposure to hard mask-forming precursors and reactants, e.g. bulky or long chain hydrocarbon groups, such as isopropyl, tert-butyl, n-hexyl, or phenyl; e.g. alkyl silyl groups, such as trimethylsilyl and triethylsilyl groups.

In some embodiments, the inhibitor comprises a moiety selected from alkyl, alkenyl, alkynyl, aryl, fluoroalkyl, fluoroalkenyl, fluoroalkynyl, fluoroaryl, and amino.

In some embodiments, the inhibitor comprises an organic compound. In some embodiments, the inhibitor comprises a compound selected from the list consisting of alkylamines, halogenated carbons, and alkanolamines. In some embodiments, the inhibitor is selected from the list consisting of butylamine, hexylamine, diisopropylamine, hexafluoro-2-propanol, ethanolamine, and ethylenediamine.

In some embodiments, the inhibitor comprises one or more of silicon and germanium. In some embodiments, the inhibitor comprises one or more inorganic elements. In some embodiments, the inhibitor comprises a compound selected from the list consisting of silazanes, silylamines, alkylgermanes, aminogermanes, and heterocyclic compounds. In some embodiments, the inhibitor is selected from the list consisting of hexamethyldisilazane, dimethyltrimethylsilylamine, chlorotrimethylgermane, 2 2-dimethoxy-1 6-diazo-2-silacyclooctene.

An exemplary ALD pulsing scheme is shown in FIG. 3. Such a pulsing scheme can be suitable used for forming a layer as described herein, such as an EUV resist or a hard mask. In particular, the embodiment of FIG. 3 comprises a step 311 of positioning a substrate on a substrate support, after which a plurality of deposition cycles 318 are executed. Ones from the plurality of deposition cycles 318 comprise a precursor pulse 312 and a reactant pulse 314. Optionally, precursor pulses 312 can be followed by post precursor purges 313. Optionally, reactant pulses 314 can be followed by post reactant purges 315. After a suitable amount of deposition cycles 318 have been executed, a layer has been formed on the substrate, and the method ends 316.

Further described herein is a system that comprises one or more precursor sources, a reaction chamber operationally coupled with the one or more precursor sources, and a controller. The controller is constructed and arranged for causing the system to carry out a method as described herein.

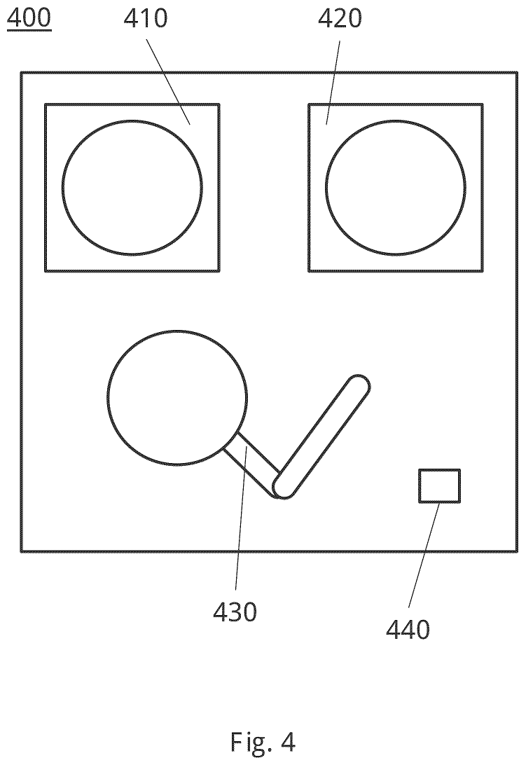

Referring to FIG. 4, further described herein is a system 400 that comprises a first reaction chamber 410, a second reaction chamber 420, and a wafer handling robot 430. The system 400 can further comprise a controller 440 which can be constructed and arranged for causing the system to execute a method as described herein.

In some embodiments, the first reaction chamber 410 is constructed and arranged for forming a resist, e.g. an EUV resist, on the substrate, the wafer handling robot 430 is constructed and arranged for transporting a substrate from the first reaction chamber 410 to the second reaction chamber without breaking vacuum, and the second reaction chamber 420 is constructed and arranged for forming a passivation layer on the EUV resist. Thus the first reaction chamber 410 and the second reaction chamber 420 can be dedicated to a single deposition step, which can be advantageous for some deposition chemistries.

In some embodiments, each of the first reaction chamber 410 and the second reaction chamber 420 are constructed and arranged for forming a resist, e.g. an EUV resist, on the substrate, and for forming a passivation layer on the EUV resist. In such embodiments, the wafer handling robot 430 is constructed and arranged for transporting substrates in parallel to and from the first reaction chamber 410 and the second reaction chamber 420. Thus, the first and second reaction chamber can have an identical construction and configuration, thereby providing redundancy which can result in excellent tool uptime.

Of course, the system 400 can comprise further reaction chambers such as thermal or plasma-enhanced atomic layer deposition (ALD) reaction chambers and thermal or plasma-enhanced chemical vapor deposition (CVD) reaction chambers. The wafer handling robot 430 can optionally be constructed and arranged for moving substrates to, from, and between the various reaction chambers comprised in the system 400.

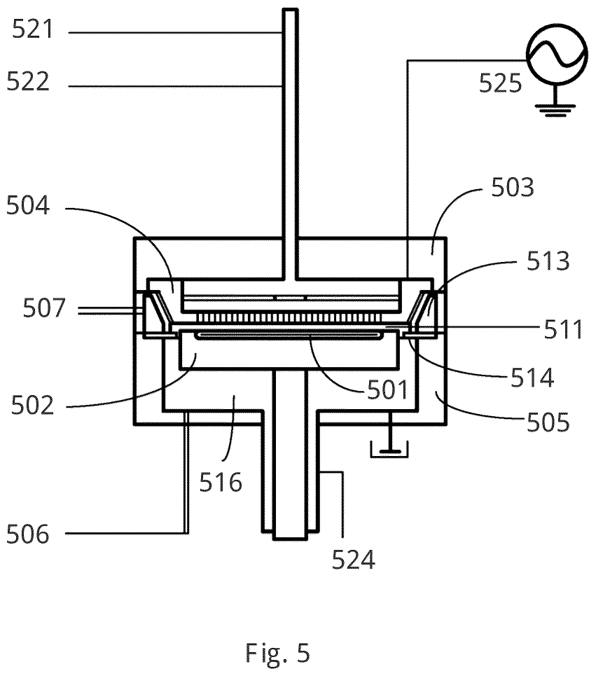

Layers formed in methods according to the present disclosure may be formed in any suitable apparatus, including in a reactor as shown in FIG. 5. Similarly, the presently provided structures or parts thereof may be manufactured in any suitable apparatus, including a reactor as shown in FIG. 5. FIG. 5 is a schematic view of an embodiment of a plasma-enhanced atomic layer deposition (PEALD) apparatus, desirably in conjunction with controls programmed to conduct the sequences described below, usable in some embodiments of the present disclosure. In this figure, by providing a pair of electrically conductive flat-plate electrodes 502,504 in parallel and facing each other in the interior 511 (reaction zone) of a reaction chamber 503, applying RF power (e.g. at 13.56 MHz and/or 27 MHz) from a power source 525 to one side, and electrically grounding the other side 512, a plasma is excited between the electrodes. A temperature regulator may be provided in a lower stage 502, i.e. the lower electrode. A substrate 501 is placed thereon and its temperature is kept constant at a given temperature. The upper electrode 504 can serve as a shower plate as well, and a reactant gas and/or a dilution gas, if any, as well as a precursor gas can be introduced into the reaction chamber 503 through a gas line 521 and a gas line 522, respectively, and through the shower plate 504. Additionally, in the reaction chamber 503, a circular duct 513 with an exhaust line 517 is provided, through which the gas in the interior 511 of the reaction chamber 503 is exhausted. Additionally, a transfer chamber 505 is disposed below the reaction chamber 503 and is provided with a gas seal line 524 to introduce seal gas into the interior 511 of the reaction chamber 503 via the interior 516 of the transfer chamber 505 wherein a separation plate 514 for separating the reaction zone and the transfer zone is provided. Note that a gate valve through which a wafer may be transferred into or from the transfer chamber 505 is omitted from this figure. The transfer chamber is also provided with an exhaust line 506.

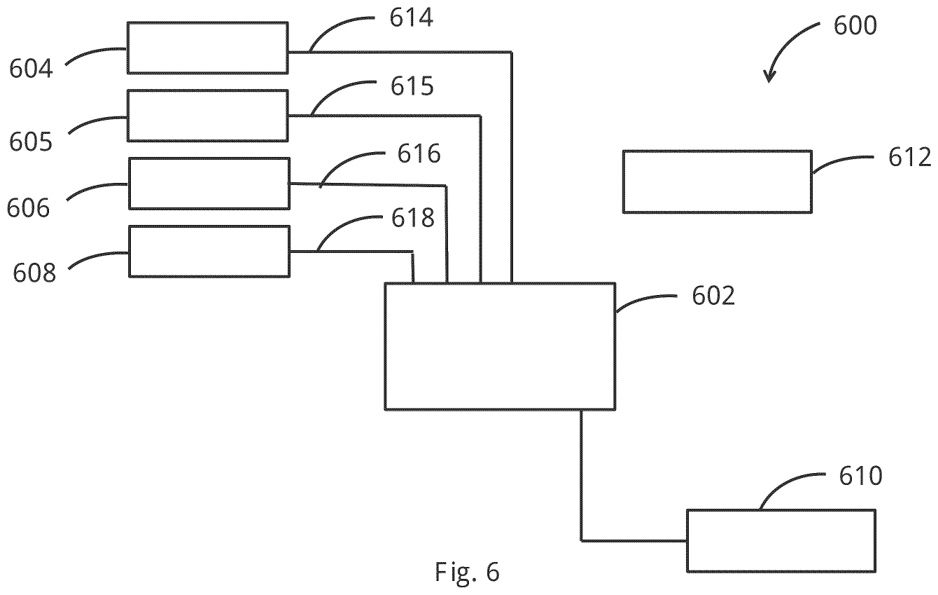

FIG. 6 illustrates a system 600 in accordance with exemplary embodiments of the disclosure. The system 600 can be used to perform a method as described herein and/or form a structure or device portion as described herein.

In the illustrated example, the system 600 includes one or more reaction chambers 602, a first precursor gas source 604, a reactant gas source 606, a purge gas source 608, an exhaust 610, and a controller 612.

The reaction chamber 602 can include any suitable reaction chamber, such as an ALD or CVD reaction chamber.

The first precursor gas source 604 can include a vessel and one or more precursors as described herein-alone or mixed with one or more carrier (e.g., noble) gases. The transition metal precursor gas source 606 can include a vessel and one or more reactants as described herein-alone or mixed with one or more carrier gases. The purge gas source 608 can include one or more noble gases as described herein. Although illustrated with four gas sources 604-608, the system 600 can include any suitable number of gas sources. The gas sources 604-608 can be coupled to reaction chamber 602 via lines 614-618, which can each include flow controllers, valves, heaters, and the like.

The exhaust 610 can include one or more vacuum pumps.

The controller 612 includes electronic circuitry and software to selectively operate valves, manifolds, heaters, pumps and other components included in the system 600. Such circuitry and components operate to introduce precursors and purge gases from the respective sources 604-608. The controller 612 can control timing of gas pulse sequences, temperature of the substrate and/or reaction chamber, pressure within the reaction chamber, and various other operations to provide proper operation of the system 600. The controller 612 can include control software to electrically or pneumatically control valves to control flow of precursors, reactants and purge gases into and out of the reaction chamber 602. The controller 612 can include modules such as a software or hardware component, e.g., a FPGA or ASIC, which performs certain tasks. A module can advantageously be configured to reside on the addressable storage medium of the control system and be configured to execute one or more processes.

Other configurations of the system 600 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber 602. Further, as a schematic representation of a system, many components have been omitted for simplicity of illustration, and such components may include, for example, various valves, manifolds, purifiers, heaters, containers, vents, and/or bypasses.

During operation of the reactor system 600, substrates, such as semiconductor wafers (not illustrated), are transferred from, e.g., a substrate handling system to the reaction chamber 602. Once substrate(s) are transferred to the reaction chamber 602, one or more gases from the gas sources 604-608, such as precursors, reactants, carrier gases, and/or purge gases, are introduced into the reaction chamber 602.

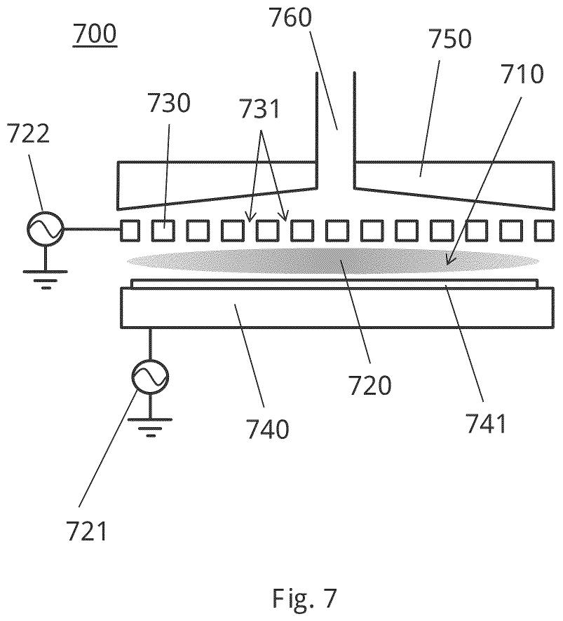

FIG. 7 shows a schematic representation of an embodiment of a sub-system 700 as described herein. It can be used, for example, for forming at least one of an EUV resist, a passivation layer, and a hard mask. Additionally or alternatively, it can be employed for etching one or more of a gap filling fluid and a material layer. The sub-system 700 comprises a reaction chamber 710 in which a plasma 720 is generated. In particular, the plasma 720 is generated between a showerhead injector 730 and a substrate support 740. This is a direct plasma configuration employing a capacitively coupled plasma.

In the configuration shown, the sub-system 700 comprises two alternating current (AC) power sources: a high frequency power source 721 and a low frequency power source 722. In the configuration shown, the high frequency power source 721 supplies radio frequency (RF) power to the showerhead injector, and the low frequency power source 722 supplies an alternating current signal to the substrate support 740. The radio frequency power can be provided, for example, at a frequency of 13.56 MHz or higher, e.g. at a frequency of at least 100 kHz to at most 50 MHz, or at a frequency of at least 50 MHz to at most 100 MHz, or at a frequency of at least 100 MHz to at most 200 MHz, or at a frequency of at least 200 MHz to at most 500 MHZ, or at a frequency of at least 500 MHz to at most 1000 MHz, or at a frequency of at least 1000 MHz to at most 2000 MHz. The low frequency alternating current signal can be provided, for example, at a frequency of 2 MHz or lower, such as at a frequency of at least 100 kHz to at most 200 kHz, or at a frequency of at least 200 kHz to at most 500 kHz, or at a frequency of at least 500 kHz to at most 1000 kHz, or at a frequency of at least 1000 kHz to at most 2000 kHz. Process gas comprising precursor, reactant, or both, is provided through a gas line 760 to a conical gas distributor 750. The process gas then passes through holes 731 in the showerhead injector 730 to the reaction chamber 710.

Whereas the high frequency power source 721 is shown as being electrically connected to the showerhead injector, and the low frequency power source 722 is shown as being electrically connected to the substrate support 740, other configurations are possible as well. For example, in some embodiments (not shown), both the high frequency power source and the low frequency power source can be electrically connected to the showerhead injector; or both the high frequency power source and the low frequency power source can be electrically connected to the substrate support; or the high frequency power source can be electrically connected to the substrate support, and the low frequency power source can be electrically connected to the showerhead injector.

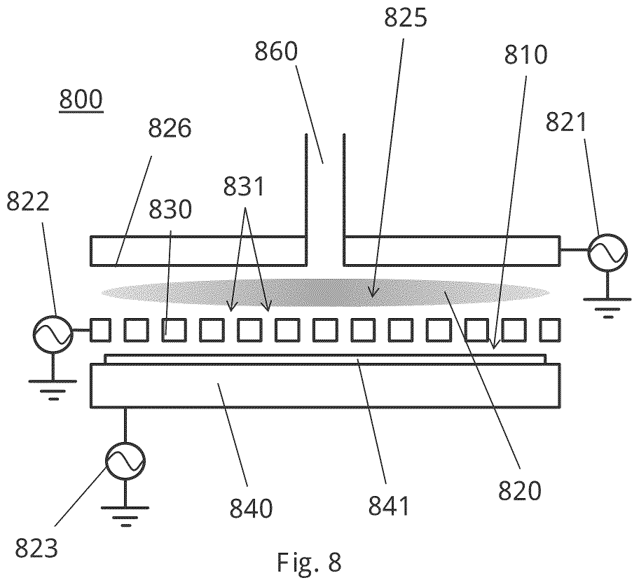

FIG. 8 shows a schematic representation of another embodiment of a sub-system 800 as described herein. It can be used, for example, for forming at least one of an EUV resist, a passivation layer, and a hard mask. The configuration of FIG. 8 can be described as an indirect plasma system. The sub-system 800 comprises a reaction chamber 810 which is separated from a plasma generation space 825 in which a plasma 820 is generated. In particular, the reaction chamber 810 is separated from the plasma generation space 825 by a showerhead injector, and the plasma 820 is generated between the showerhead injector 830 and a plasma generation space ceiling 826.

In the configuration shown, the sub-system 800 comprises three alternating current (AC) power sources: a high frequency power source 821 and two low frequency power sources 822,823: a first low frequency power source 822 and a second low frequency power source 823. In the configuration shown, the high frequency power source 821 supplies radio frequency (RF) power to the plasma generation space ceiling, the first low frequency power source 822 supplies an alternating current signal to the showerhead injector 830, and the second low frequency power source 823 supplies an alternating current signal to the substrate support 840. A substrate 841 is provided on the substrate support 840. The radio frequency power can be provided, for example, at a frequency of 13.56 MHz or higher. The low frequency alternating current signal of the first and second low frequency power sources 822,823 can be provided, for example, at a frequency of 2 MHz or lower.

Process gas comprising precursor, reactant, or both, is provided through a gas line 860 that passes through the plasma generation space ceiling 826, to the plasma generation space 825. Active species such as ions and radicals generated by the plasma 825 from the process gas pass through holes 831 in the showerhead injector 830 to the reaction chamber 810.

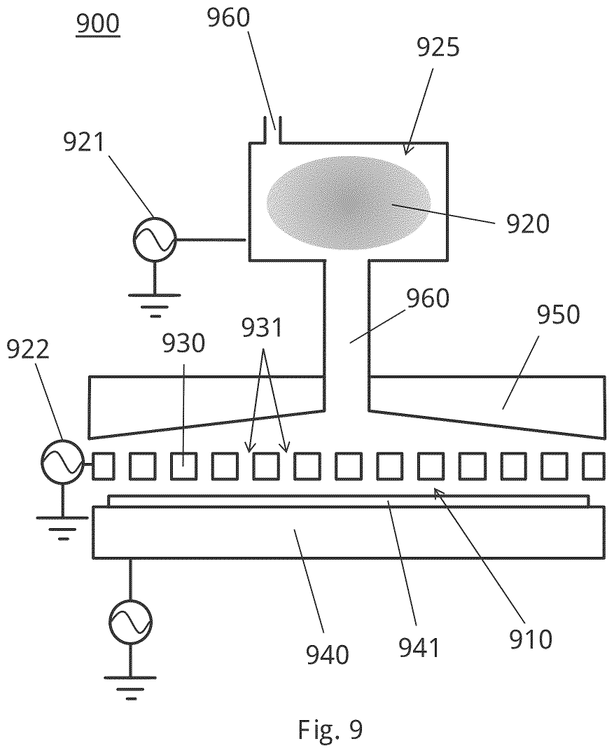

FIG. 9 shows a schematic representation of another embodiment of a sub-system 900 as described herein. It can be used, for example, for forming at least one of an EUV resist, a passivation layer, and a hard mask. The configuration of FIG. 9 can be described as a remote plasma system. The sub-system 900 comprises a reaction chamber 910 which is operationally connected to a remote plasma source 925 in which a plasma 920 is generated. Any sort of plasma source can be used as a remote plasma source 925, for example an inductively coupled plasma, a capacitively coupled plasma, or a microwave plasma.

In particular, active species are provided from the plasma source 925 to the reaction chamber 910 via an active species duct 960, to a conical distributor 950, through holes 931 in a shower plate injector 930, to the reaction chamber 910. Thus, active species can be provided to the reaction chamber in a uniform way.

In the configuration shown, the sub-system 900 comprises three alternating current (AC) power sources: a high frequency power source 921 and two low frequency power sources 9221923: a first low frequency power source 922 and a second low frequency power source 923. In the configuration shown, the high frequency power source 921 supplies radio frequency (RF) power to the plasma generation space ceiling, the first low frequency power source 922 supplies an alternating current signal to the showerhead injector 930, and the second low frequency power source 923 supplies an alternating current signal to the substrate support 940. A substrate 941 is provided on the substrate support 940. The radio frequency power can be provided, for example, at a frequency of 13.56 MHz or higher. The low frequency alternating current signal of the first and second low frequency power sources 922,923 can be provided, for example, at a frequency of 2 MHz or lower.

In some embodiments (not shown), an additional high frequency power source can be electrically connected to the substrate support. Thus, a direct plasma can be generated in the reaction chamber.

Process gas comprising precursor, reactant, or both, is provided to the plasma source 925 by means of a gas line 960. Active species such as ions and radicals generated by the plasma 925 from the process gas are guided to the reaction chamber 910.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A structure comprising a substrate, an extreme ultraviolet (EUV) resist, and an inhibition layer,
wherein the EUV resist comprises exposed resist areas and unexposed resist areas, and,
wherein the inhibition layer inhibits the unexposed resist areas versus the exposed resist areas with respect to vapor phase deposition of a hard mask.

2. The structure according to claim 1 further comprising the hard mask on the exposed resist areas.

3. The structure according to claim 1, wherein the inhibition layer comprises a surface termination selected from alkyl, alkenyl, alkynyl, aryl, fluoroalkyl, fluoroalkenyl, fluoroalkynyl, fluoroaryl, and amino.

4. The structure according to claim 1, wherein the EUV resist is selected from a metal oxide resist, chemically amplified resist, and acrylate polymer-based resist.

5. The structure according to claim 1, wherein the EUV resist comprises a metalorganic framework.

6. The structure according to claim 1, wherein the hard mask comprises one or more materials selected from metals, semiconductors, and dielectrics.

7. The structure according to claim 1, wherein the inhibition layer comprises a surface group selected from the list consisting of alkyl, alkenyl, alkynyl, aryl, fluoroalkyl, fluoroalkenyl, fluoroalkynyl, fluoroaryl, and amino.

8. The structure according to claim 1, wherein the exposed resist comprises one or more surface terminations selected from dangling bond, carboxyl, hydroxyl, and amine.

9. A method of forming a structure, the method comprising:
providing a substrate;
forming an EUV resist on the substrate; and,
contacting the substrate with an inhibitor, thereby forming an inhibition layer on the EUV resist,
wherein, upon EUV exposure through a mask, exposed resist areas and unexposed resist areas are formed, the unexposed resist areas being inhibited by the inhibition layer.

10. The method according to claim 9 that further comprises exposing the substrate through a mask, thereby forming the exposed resist areas and the unexposed resist areas, the unexposed resist areas being inhibited by the inhibition layer versus the exposed resist areas with respect to vapor phase deposition of a hard mask.

11. The method according to claim 9, wherein the inhibitor comprises a compound having the formula (R1)ₙ(M)(R2)₄₋ₙ, wherein R1 is an attaching group selected from halogen, amine, alkylamine, dialkylamine, wherein M is Si or Ge, wherein R2 is a protecting group selected from a C1 to C8 hydrocarbyl, and wherein n is an integer from at least 1 to at most 3.

12. The method according to claim 11, wherein R2 is selected from the list consisting of alkyl, alkynyl, fluorohydrocarbyl, C1-C8 saturated or unsaturated linear hydrocarbyl, and aryl.

13. The method according to claim 11, wherein n equals 1.

14. The method according to claim 9, wherein the inhibitor comprises one or more of an acyl halide, an acid anhydride, and a haloalkylphosphine.

15. The method according to claim 9 that further comprises selectively depositing a hard mask on the exposed resist areas with respect to the unexposed resist areas.

16. The method according to claim 15, wherein the hard mask is selectively deposited using a vapor phase deposition technique selected from molecular layer deposition, atomic layer deposition, and chemical vapor deposition.

17. The method according to claim 10, wherein the hard mask is deposited at a temperature of at most 150° C.

18. The method according to claim 10, wherein the hard mask comprises an oxide.

19. The method according to claim 9, wherein the EUV resist is formed by molecular layer deposition.

20. A system comprising one or more precursor sources, a reaction chamber operationally coupled with the one or more precursor sources, and a controller, the controller being arranged for causing the system to carry out a method according to claim 9.
